(19) United States
(12) Patent Application Publication
(10) Pub. No.: US 2006/0105541 A1
(43) Pub. Date: May 18, 2006

(54) Trench isolation method for semiconductor devices

(76) Inventor: Yushi Inoue, Hiroshima (JP)

Correspondence Address: HARNESS, DICKEY & PIERCE, P.L.C., P.O. BOX 8910, RESTON, VA, 20195, US

(21) Appl. No.: 11/272,668

(22) Filed: Nov. 15, 2005

(30) Foreign Application Priority Data
Nov. 15, 2004 (JP) 2004-330766

(51) Int. Cl. H01L 21/76

(52) U.S. Cl. 438/452

(57) ABSTRACT

A trench isolation method for semiconductor devices, the method includes the steps of: successively depositing a pad oxide film and a nitride film on a semiconductor substrate and then selectively removing the pad oxide film and the nitride film to form a mask pattern; forming trench regions in the semiconductor substrate using the formed mask pattern; depositing a thermal oxide film on side walls and bottoms of the formed trench regions by thermal oxidation; depositing on the semiconductor substrate having the trench regions a first buried oxide film having such a thickness that the trench regions are not completely filled by thermal CVD using SiH₄/N₂O gas; depositing a plasma oxide film as a second buried oxide film, by HDP plasma CVD, such that the trench regions are filled with the film; and removing upper portions of the first and second buried oxide films by CMP (chemical mechanical polishing) using the nitride film as a stopper and then etching away the nitride film and the pad oxide film, wherein the gas flow-rate ratio of SiH₄/N₂O is set to such a ratio that formation of fine foreign substances in the first buried oxide film can be suppressed in the step of depositing the first buried oxide film.

### CROSS-REFERENCE TO RELATED APPLICATION

This application is related to Japanese application No.2004-330766 filed on Nov. 14, 2004 whose priority is claimed under 35 USC § 119, the disclosure of which is incorporated by reference in its entirety.

### BACKGROUND OF THE INVENTION

1. Field of the Invention

The present invention relates to a method for fabricating a trench isolation configuration in a semiconductor substrate and, more particularly, it relates to a trench isolation configuration fabricating method which is capable of preventing the formation of concave portions at the surface of an oxide film buried within the trenches and preventing the occurrence of voids within the oxide film buried in the trenches.

2. Description of the Related Art

As a technique for electrically isolating devices formed on a semiconductor substrate from one another, there have been known trench isolation configurations (Shallow Trench Isolation: STI) consisting of trenches formed in a semiconductor substrate and insulation film buried therein. However, when the widths of trench regions are reduced with the progress of miniaturization of devices and, for example, they are made to be 0.5 micrometer or less, voids are generated, namely portions of the trench regions are not completely filled with the insulation film. There has been known a method which deposits a first thermal oxide film with a small thickness on the side walls and the bottoms of formed trench regions and then completely fills the trench regions with a second oxide film with a high density, in order to reduce the occurrence of voids.

FIGS. 5A to 5D and 6E to 6G illustrate a conventional method for fabricating an STI configuration. According to the conventional method, as illustrated in FIG. 5A, a pad oxide film 2 and a nitride film 3 are successively formed on a semiconductor substrate 1 and then a resist mask pattern 4 is formed thereon. Next, as illustrated in FIG. 5B, a trench mask pattern is formed by using the resist mask pattern. Then, as illustrated in FIG. 5C, dry etching is applied to the semiconductor substrate 1 using the trench mask pattern to form trench regions 5. Subsequently, as illustrated in FIG. 5D, a thermal oxide film 6 is formed on the side walls and the bottoms of the trench regions, through thermal oxidation. Next, as illustrated in FIG. 6E, an oxide film 7 is formed such that the insides of the trenches are completely filled therewith. Next, as illustrated in FIG. 6F, chemical mechanical polishing (CMP) is applied thereto by using the nitride film 3 as a stopper. Finally, as illustrated in FIG. 6G, the nitride film 3 is removed through wet etching. Subsequently, wet etching is properly applied to the oxide film.

In this case, as illustrated in FIG. 6G, concave portions 8, which are called divots, are formed on the surface of the oxide film buried in the trenches. When transistors are formed on the STI configuration, such concave portions induce concentrations of electric fields at the corner portions of the concave portions, thus resulting in malfunctions in their electric characteristics. Furthermore, crystal defects may be induced in the semiconductor substrate 1 around the trenches 5, due to physical stresses in the buried oxide film 7.

To cope with the aforementioned problems, there is a method which deposits a liner film as a first buried oxide film before forming a high-density plasma (HDP) oxide film as a second buried oxide film and, subsequently, deposits the second buried oxide film, as disclosed in Japanese Unexamined Patent Publication No. Hei 11(1999)-176924 and No. 2001-135718, for example.

With the progress of miniaturization of LSIs, trench widths decreases to 0.2 micrometer or less, which increases the difficulty of burying of an oxide film within trench regions and further increases the influences of divots 8 as illustrated in FIG. 6G on the transistor characteristics. Further, the variations in the quality and the thickness of the liner film exert influences on the variation of the insulation characteristic of the device isolation.

### SUMMARY OF THE INVENTION

The inventors found that, with conventional methods which form a liner film as described above, voids 13 may be generated within the second buried oxide film due to fine foreign substances 12 existing in a liner film 11, as illustrated in FIGS. 4E to 4G. It is deemed that such fine foreign substances 12 are oxide-based particles, and also it is deemed that excessive SiH₄ causes gas-phase reactions with N₂O in gas phase to form oxide-based particles and these oxide-based particles are adhered to the surface of the liner oxide film being deposited. Such voids cause degradation of the device isolation characteristics and also cause non-uniformity of the field-oxide-film configuration as illustrated in FIG. 4H. Consequently, when gate electrodes are formed on the STI configuration, opens and shorts of the game electrodes may occur.

The present invention provides a trench-isolation configuration fabricating method which is capable of preventing the formation of divots in the trench isolation regions and effectively suppressing the occurrence of voids within the trench regions.

The present invention provides a trench isolation method for semiconductor devices, the method comprising the steps of: successively depositing a pad oxide film and a nitride film on a semiconductor substrate and then selectively removing the pad oxide film and the nitride film to form a mask pattern; forming trench regions in the semiconductor substrate using the formed mask pattern; depositing a thermal oxide film on side walls and bottoms of the formed trench regions by thermal oxidation; depositing on the semiconductor substrate having the trench regions a first buried oxide film having such a thickness that the trench regions are not completely filled by thermal CVD using SiH₄/N₂O gas; depositing a plasma oxide film as a second buried oxide film, by HDP plasma CVD, such that the trench regions are filled with the film; and removing upper portions of the first and second buried oxide films by CMP (chemical mechanical polishing) using the nitride film as a stopper and then etching away the nitride film and the pad oxide film, wherein the gas flow-rate ratio of SiH₄/N₂O is set to such a ratio that formation of fine foreign substances in the first buried oxide film can be suppressed in the step of depositing the first buried oxide film.

### BRIEF DESCRIPTION OF THE DRAWINGS

FIGS. 1A to 1D are substrate cross-sectional views illustrating respective steps of a fabricating method of a trench isolation configuration according to the present invention.

FIGS. 2E to 2H are substrate cross-sectional views illustrating subsequent steps to the step of FIG. 1D.

FIGS. 3A to 3D are substrate cross-sectional views illustrating respective steps of a conventional fabricating method of a trench isolation configuration, wherein there is illustrated a case where defects are generated.

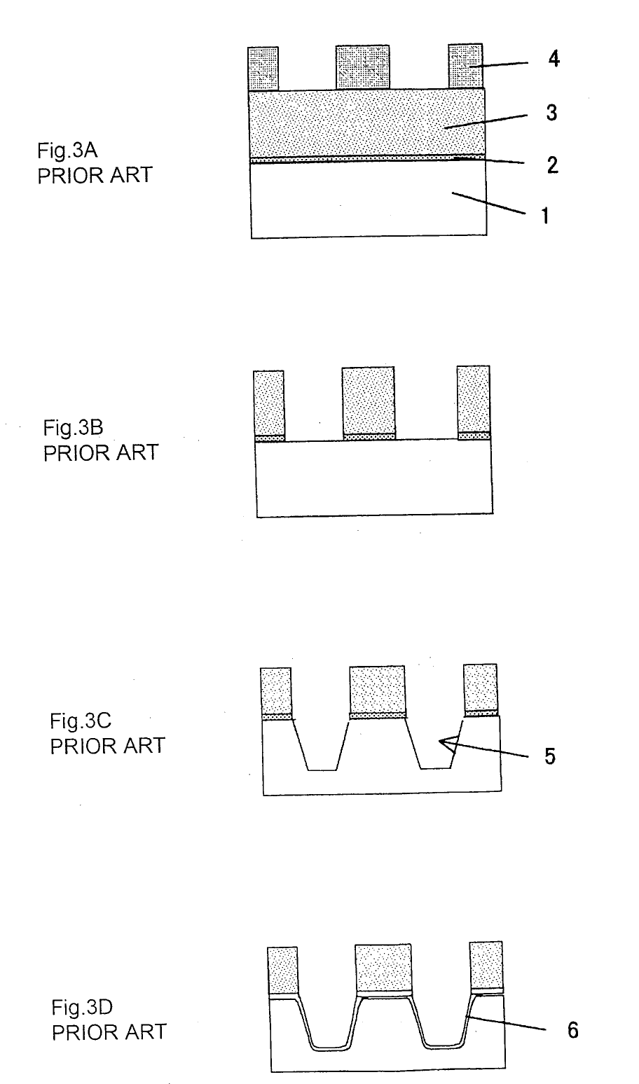

FIGS. 4E to 4H are substrate cross-sectional views illustrating subsequent steps to the step of FIG. 3D.

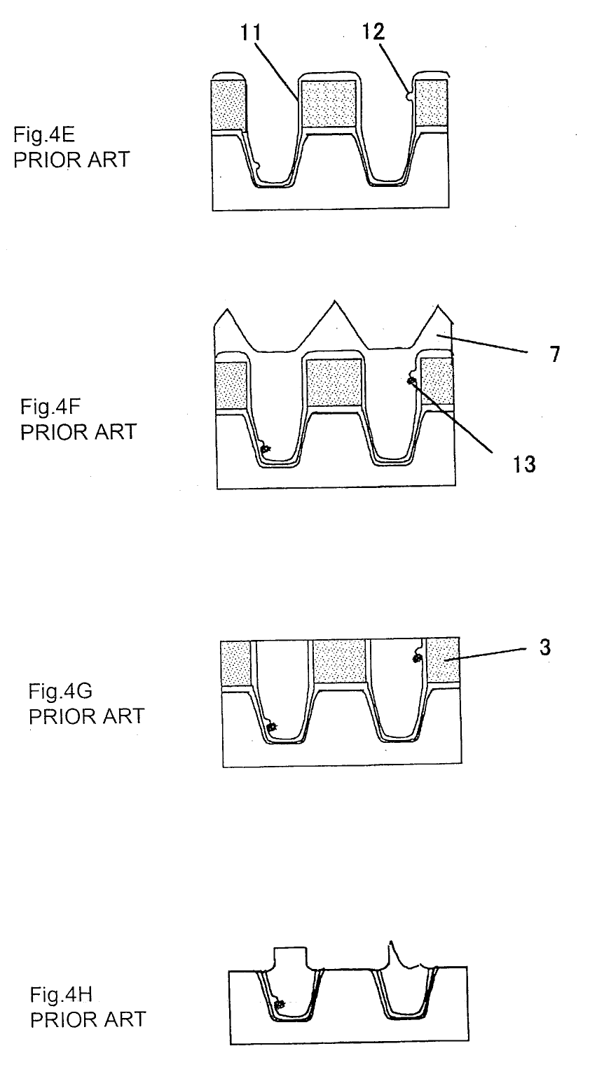

FIGS. 5A to 5D are substrate cross-sectional views illustrating respective steps of a conventional fabricating method of a trench isolation configuration.

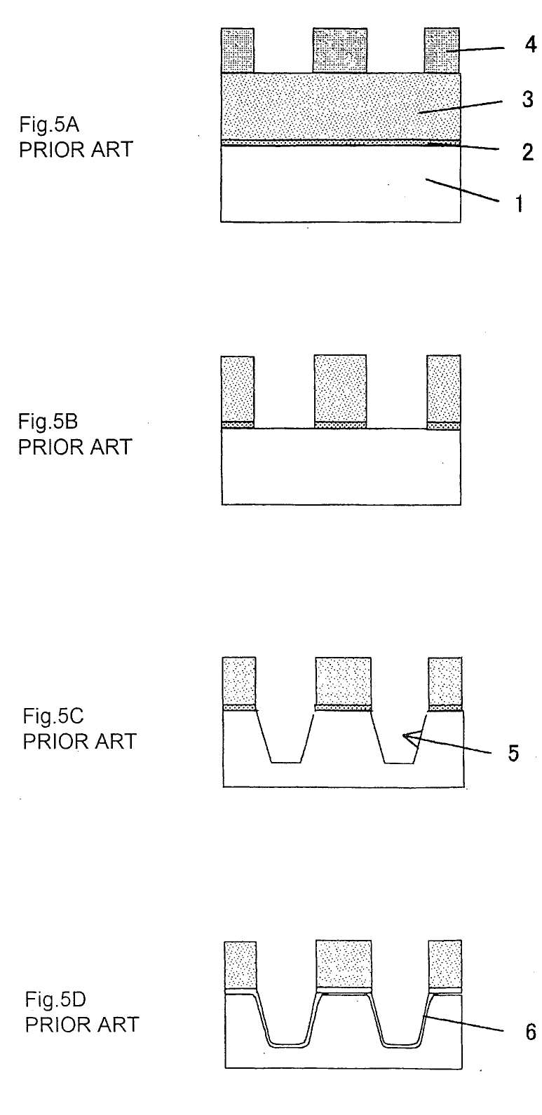

FIGS. 6E to 6G are substrate cross-sectional views illustrating subsequent steps to the step of FIG. 5D.

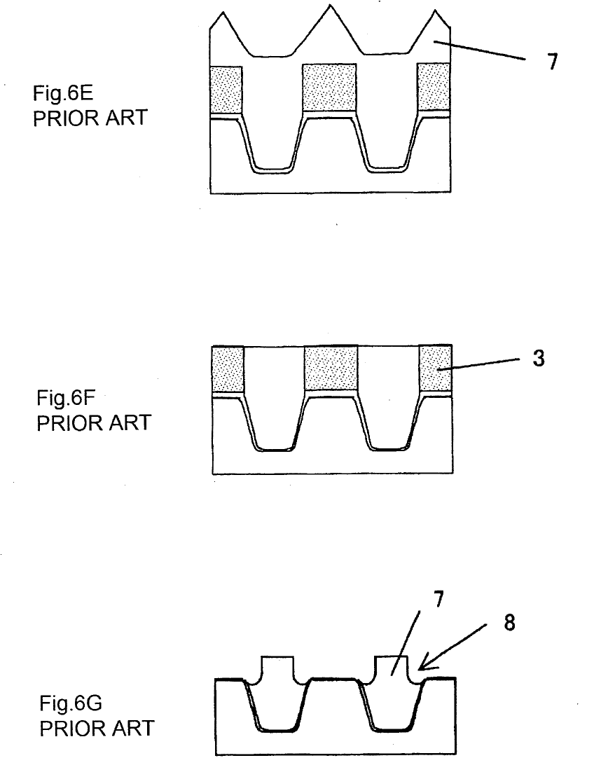

### DESCRIPTION OF THE PREFERRED EMBODIMENTS

The present invention will become more fully understood from the detailed description given hereinbelow and the accompanying drawings which are given by way of illustration only, and thus are not limitative of the present invention.

With the trench isolation method according to the present invention, the gas flow-rate ratio of SiH₄/N₂O is set to a flow-rate ratio which can suppress the formation of fine foreign substances in the first buried oxide film in the step of depositing the aforementioned first buried oxide film, which can suppress the adhesion of fine foreign substances to the first buried oxide film and also can prevent the formation of voids within the second buried oxide film which is formed on the first buried oxide film. Consequently, it is possible to suppress the occurrence of malfunctions such as opens and shorts of gate electrodes formed on the STI configuration.

In other words, with the fabricating method of a trench isolation configuration according to the present invention, it is possible to suppress the formation of divots around the surface of the oxide film buried in the trenches, thus preventing degradation of the device characteristics due to divots. Further, it is possible to prevent the occurrence of defects due to voids within the buried oxide films within the trench isolation regions, thus enhancing the reliability of the devices.

In a trench isolation method according to the present invention, a thermal oxide film is deposited on the side walls and the bottoms of trench regions and, then, an HTO (High Temperature Oxide) oxide film as a liner oxide film is deposited using SiH₄/N₂O gas, wherein the aforementioned HTO oxide film is deposited under a condition where the gas flow-rate ratio of SiH₄/N₂O is within the range of from 1/500 to 1/70, in order to suppress the occurrence of fine foreign substances.

More specifically, the trench isolation method according to the present invention includes a step of successively depositing a pad oxide film and a nitride film on a semiconductor substrate, then selectively removing them to form a mask pattern, and then forming trench regions in the semiconductor substrate using the mask pattern, a step of depositing a thermal oxide film on the side walls and the bottoms of the trench regions, a step of depositing on the semiconductor substrate having the trench regions a first buried oxide film with such a thickness that the trench regions are not completely filled by thermal CVD using SiH₄/H₂O gas, a step of depositing a plasma oxide film as a second buried oxide film by HDP plasma CVD such that the trench regions are filled with the film, and a step of removing the upper portions of the first and second buried oxide films by CMP (chemical mechanical polishing) using the nitride film as a stopper and then etching away the nitride film and the pad oxide film, wherein the gas flow-rate ratio of SiH₄/N₂O is set to such a ratio that formation of fine foreign substances in the first buried oxide film can be suppressed in the step of depositing the first buried oxide film.

Preferably, the material of the semiconductor substrate is silicon. The pad oxide film is a film having the function of alleviating stresses generated between the silicon substrate and the nitride film and, such a pad oxide film may be formed by, for example, thermal oxidation. The nitride film on the pad oxide film may be formed by, for example, CVD. The selective removing of the aforementioned pad oxide film and the nitride film may be realized by patterning a photo resist on the surface through photolithography technique and then applying an isotropic dry etching thereto. Further, the trench regions may be formed by etching the silicon substrate through a dry etching method using, as a mask, the nitride film which has been selectively partially removed.

Further, a thickness that does not completely fill the trench regions is, for example, a thickness within the range of about 5 to 50 nm (nanometers), in the case where the trench width is 200 nm. In this case, accordingly, grooves with a width of at least about 100 nm are left within the respective trench regions, after the formation of the first buried oxide film.

Preferably, the gas flow-rate ratio of SiH₄/N₂O is within the range of 1/500 to 1/70 in the step of depositing the first buried oxide film. By setting the gas flow-rate ratio of SiH₄/N₂O within the aforementioned range, it is possible to suppress the formation of oxide-based particles due to gas-phase reactions of excessive SiH₄ with N₂O in gas phase, thereby suppressing the formation of fine foreign substances at the surface region of the first buried oxide film in the aforementioned step.

More preferably, the gas flow-rate ratio of SiH₄/N₂O is within the range of 1/250 to 1/100 in the step of depositing the first buried oxide film.

Preferably, the step of depositing a thermal oxide film on the side walls and the bottoms of the trench regions by thermal oxidation includes two thermal oxidation treatments. Namely, it is preferable that the first buried oxide film is deposited by repeatedly performing, plural times, a hydrofluoric-acid pretreatment and a subsequent oxidation, in order to perform rounding-oxidation for suppressing the concentrations of electric fields at the trench corner portions. However, an excessive number of oxidations will induce side etching of the pad oxide film, thus resulting in pattern abnormalities. Therefore, it is preferable that oxidation is performed twice.

Further, preferably, the deposition temperature is within the range of 700 to 820° C. in the step of depositing the first buried oxide film.

Further, in the trench isolation method for semiconductor devices according to the present invention, the step of depositing the first buried oxide film may include a heat treatment for increasing the density of the formed first buried oxide film, after the formation of the first buried oxide film. The temperature of the aforementioned heat-treatment is preferably within the range of 900 to 1100 degree. C. By increasing the density of the first buried oxide film, it is possible to reduce the etching rate of the first buried oxide film and increase the etching ratio of the nitride film and the pad oxide film with respect to the first buried oxide film, during the etching of the nitride film and the pad oxide film in the subsequent step.

Further, preferably, the step of depositing the second buried oxide film includes a heat treatment for increasing the density of the formed second buried oxide film, after the formation of the second buried oxide film. The temperature during the aforementioned heat-treatment may be within the range of 900 to 1100 degree. C. Namely, in the case of completely burying a high-density plasma (HDP) oxide film in the trench regions after the formation of the first buried oxide film, it is desirable that high-temperature heat treatments are applied before and after the formation of the HDP oxide film, in order to increase the density of the oxide films for suppressing the occurrence of divots and enhancing the device isolation characteristic. By increasing the density of the second buried oxide film, it is possible to reduce the etching rate of the second buried oxide film and increase the etching ratio of the nitride film and the pad oxide film with respect to the second buried oxide film, during the etching of the nitride film and the pad oxide film in the subsequent step.

Further, since the liner film is made of an HTO oxide film formed using a SiH₄-based gas that is used for the formation of the HDP oxide film, the quality of the oxide film within the trenches may be made substantially uniform, thus providing a trench isolation configuration with electrical and dimensional stability, in comparison with cases of using a nitride film or an oxide film formed using SiH₂Cl₂ or TEOS.

Hereinafter, an embodiment of the present invention will be described in detail with reference to the drawings.

### Embodiments

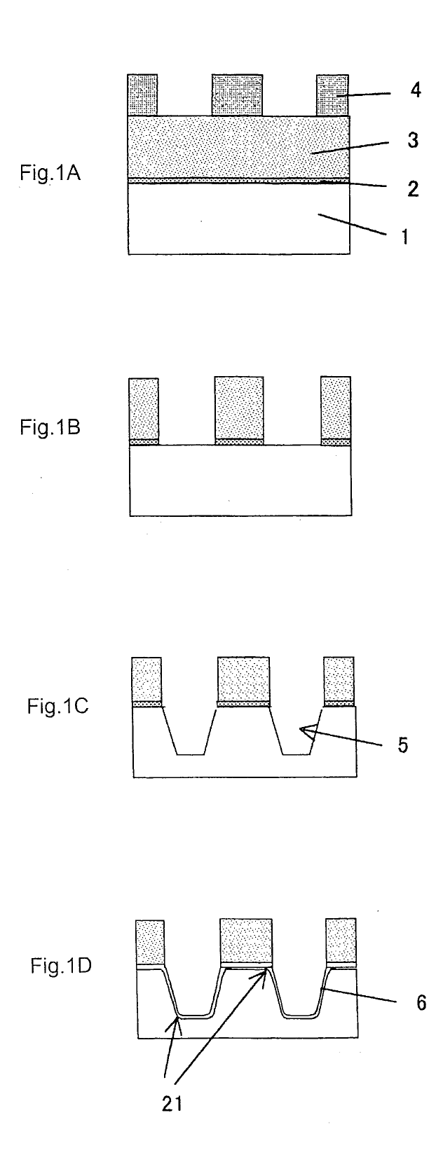

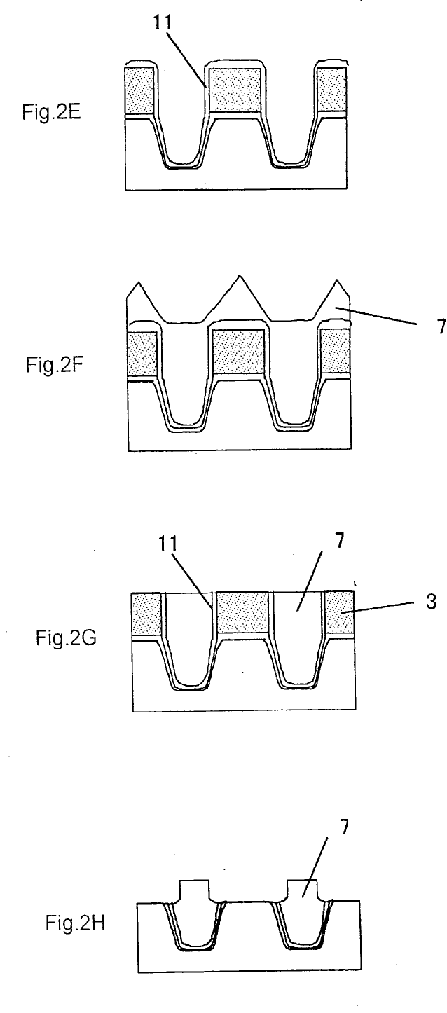

FIGS. 1A to 1D and 2E and 2H are cross-sectional views of the respective steps illustrating a fabricating method of a trench isolation configuration according to an embodiment.

First, as illustrated in FIG. 1A, a pad oxide film 2 with a thickness of about 10 nm and a nitride film 3 with a thickness of about 160 nm are formed on a silicon substrate 1 and then a resist pattern 4 is formed thereon through photolithography.

Next, as illustrated in FIG. 1B, dry etching is applied thereto using the resist pattern 4 to form a trench mask pattern.

Next, as illustrated in FIG. 1C, dry etching is applied to the silicon substrate 1 using the trench mask pattern to form trenches 5 with a depth of about 200 nm.

Next, as illustrated in FIG. 1D, rounding oxidation is performed twice to form a thermal oxide film 6 with a thickness of about 20 nm on the side walls and the bottoms of the trenches 5. The purpose of the rounding oxidation is to prevent the concentration of electric fields at the trench corner portions 21 which causes degradation of the transistor characteristics, when transistors are formed on the silicon substrate.

Next, as illustrated in FIG. 2E, a liner oxide film 11 with a thickness of about 20 nm, as a first buried oxide film, is deposited by low-pressure CVD (HTO) at a temperature within the range of about 700 to 800° C. using SiH₄/N₂O gas, under a condition where the gas flow-rate ratio of SiH₄/N₂O is equal to or less than 1/70. At this time, the deposition pressure is within the range of about 0.5 to 1.0 Torrs. In this case, the thickness of the liner oxide film 11 is such that, when the oxide film has been deposited within the trenches 5, the trenches 5 are not completely filled therewith and a groove is left within each of the trenches 5. In order to achieve this, it is preferable that the thickness of the liner oxide film 11 is within the range of 5 to 50 nm, although it depends on the trench isolation width. In such a case, since the gas flow-rate ratio of SiH₄/N₂O is equal to or less than 1/70, the gas-phase reaction of SiH₄ is suppressed, thereby preventing the occurrence of fine foreign substances.

At this time, high-temperature annealing may be applied thereto at a temperature within the range of about 900 to 1100° C. in an atmosphere of an inert gas such as N₂ for about 60 minutes, in order to increase the density of the liner oxide film for reducing the wet etching rate thereof.

Next, as illustrated in FIG. 2F, an HDP oxide film with a thickness of about 500 nm, as a second buried oxide film, is deposited using SiH₄ gas, such that the trench regions 5 are completely filled therewith. At this time, since the liner oxide film 11 includes no fine foreign substances which have been generated therein, the HDP oxide film can be completely buried within the trench regions 5 without generating voids.

Subsequently, high-temperature annealing is applied thereto at a temperature within the range of about 900 to 1100° C., in an atmosphere of an inert gas such as N₂, for about 60 minutes, in order to increase the density of the HDP oxide film for reducing the wet etching rate thereof.

Next, as illustrated in FIG. 2G, the upper portions of the HDP oxide film 7 and the liner oxide film 11 are removed by CMP using the nitride film 3 as a stopper.

Finally, as illustrated in FIG. 2H, the nitride film 3 is removed through wet etching using phosphoric acid and, then, the upper portions of the liner oxide film 11 and the HDP oxide film 7 and the pad oxide film 2 are removed through wet etching using hydrofluoric acid. At this time, since the liner oxide film 11 and the HDP oxide film 7 are made of the same type of film composition, the occurrence of divots and shape abnormalities due to the wet etching is prevented.

In order to confirm the effects of the present invention, the present inventors fabricated three types of silicon wafers as evaluation samples with a method similar to that of FIGS. 1A to 1D and 2E to 2H and inspected the numbers of defects (shape abnormalities) within the respective wafers by utilizing a commercially-available defect inspection measurement apparatus.

Table. 1 illustrates the result.

TABLE 1

| | | N₂O flow | The flow-rate | The number of defects |
|---|---|---|---|---|
| SiH₄ flow rate | | rate | ratio of SiH₄/N₂O | within a wafer |
| 30 | sccm | 1500 sccm | 1/50 | 73 |
| 21 | sccm | 1500 sccm | 1/71.4 | 5 |
| 15 | sccm | 1500 sccm | 1/100 | 0 |
| 6 | sccm | 1500 sccm | 1/250 | 0 |
| 3 | sccm | 1500 sccm | 1/500 | 0 |

The deposition temperature: 800° C.
Thickness: 20 nm

Table 1 indicates that the number of defects was decreased with decreasing SiH₄/N₂O flow-rate ratio and, the number of defects was 73 under the condition where the aforementioned flow-rate ratio was 1/5, while the number of defects was reduced to 5, which is substantially few in practical, under the condition where the flow-rate ratio was 1/71.4 and the number of defects was reduced to 0 and, namely, the occurrence of defects was completely suppressed, under the condition where the flow-rate ratio was 1/100. From the aforementioned results, it is proven that the flow-rate ratio of SiH₄/N₂O is preferably 1/70 or less and is more preferably 1/100 or less. Although reduction of the flow-rate ratio is preferable in view of suppression of the adhesion of foreign substance, it will cause reduction of the deposition rate and thus increase the deposition time, thereby resulting in economical disadvantages. In consideration of mass production, the lower limit of the aforementioned flow-rate ratio is 1/500, which is the lower limit of the controllable range of a gas-flow-rate controller. The flow-rate ratio which offers a greatest deposition rate is 1/250.

The invention thus described, it will be obvious that the same may be varied in many ways. Such variations are not to be regarded as a departure from the spirit and scope of the invention, and all such modifications as would be obvious to one skilled in the art are intended to be included within the scope of the following claims

1. A trench isolation method for semiconductor devices which comprises the steps of:
depositing a pad oxide film and a nitride film successively on a semiconductor substrate and then selectively removing the pad oxide film and the nitride film to form a mask pattern;
forming trench regions in the semiconductor substrate using the formed mask pattern;
depositing a thermal oxide film on side walls and bottoms of the formed trench regions by thermal oxidation;
depositing on the semiconductor substrate having the trench regions a first buried oxide film having such a thickness that the trench regions are not completely filled by thermal CVD using SiH₄/N₂O gas;
depositing a plasma oxide film as a second buried oxide film, by HDP plasma CVD, such that the trench regions are filled with the film; and
removing upper portions of the first and second buried oxide films by CMP (chemical mechanical polishing) using the nitride film as a stopper and then etching away the nitride film and the pad oxide film,
wherein the gas flow-rate of SiH₄/N₂O is set to such a ratio that formation of fine foreign substances in the first buried oxide film can be suppressed in the step of depositing the first buried oxide film.

2. The trench isolation method according to claim 1, wherein the gas flow-rate ratio of SiH₄/N₂O in the step of depositing the first buried oxide film is within the range of 1/500 to 1/70.

3. The trench isolation method according to claim 1, wherein the gas flow-rate ratio of SiH₄/N₂O in the step of depositing the first buried oxide film is within the range of 1/250 to 1/100.

4. The trench isolation method according to claim 2, wherein the deposition temperature in the step of depositing the first buried oxide film is within the range of 700 to 820° C.

5. The trench isolation method according to claim 1, wherein the step of depositing the thermal oxide film on the side walls and the bottoms of the trench regions includes a plurality of thermal oxidation treatments.

6. The trench isolation method according to claim 5, wherein the number of thermal oxidation treatments is two.

7. The trench isolation method according to claim 1, wherein the step of depositing the first buried oxide film includes a heat treatment for increasing the density of the first buried oxide film after the formation thereof.

8. The trench isolation method according to claim 7, wherein the temperature of the heat-treatment is within the range of 900 to 1100° C.

9. The trench isolation method according to claim 1, wherein the step of depositing the second buried oxide film includes a heat treatment for increasing the density of the second buried oxide film after the formation thereof.

10. The trench isolation method according to claim 9, wherein the temperature of the heat-treatment is within the range of 900 to 1100° C.

11. The trench isolation method according to claim 3, wherein the deposition temperature in the step of depositing the first buried oxide film is within the range of 700 to 820° C.
